(19) United States
(12) Patent Application Publication
(10) Pub. No.: US 2011/0035638 A1
(43) Pub. Date: Feb. 10, 2011

(54) Timing Failure Debug

(76) Inventor: Ruifeng Guo, Portland, OR (US)

Correspondence Address: MENTOR GRAPHICS CORP.;PATENT GROUP, 8005 SW BOECKMAN ROAD, WILSONVILLE, OR, 97070-7777, US

(21) Appl. No.: 12/420,047

(22) Filed: Apr. 7, 2009

Related U.S. Application Data
(60) Provisional application No. 61/042,887, filed on Apr. 7, 2008.

(51) Int. Cl. G01R 31/3177; G06F 11/25

(52) U.S. Cl. 714/726; 714/E11.155

(57) ABSTRACT

A debug flow that uses debug-friendly test patterns and logic fault diagnosis techniques to help physical fault isolation of timing failures.

### RELATED APPLICATIONS

This application claims priority under 35 U.S.C §119 to U.S. Provisional Patent Application No. 61/042,887, entitled “Silicon Debug Of Timing Failures With Debug-Oriented Scan Test Patterns,” filed on Apr. 7, 2008, and naming Ruifeng Guo et al. as inventors, which application is incorporated entirely herein by reference.

### FIELD OF THE INVENTION

The present invention is directed to a microcircuit device debug flow. Various aspects of the invention may be particularly applicable for employing debug-friendly scan test patterns to improve the efficiency of physical fault isolation of timing failures in microcircuit devices using time-resolved emission (TRE) system

### BACKGROUND OF THE INVENTION

Design debug and failure analysis is a critical phase of a product life cycle. With time-to-market pressure, quickly determining the root cause of design errors or defect mechanisms is becoming more critical to help product yield ramp-up and to save costs. Recent development of CMOS manufacturing technologies and design methodologies has impacted the debug and failure analysis techniques, however.

From the design side, scan-based design-for-test structures have been widely adopted to help circuit testing and debug. Scan-based logic fault diagnosis has been used by the industry to quickly determine the root cause of failure mechanisms. With scan-based test patterns, a general failure analysis flow consists of several steps: failure confirmation, failure log collection, scan-based logic fault diagnosis, and physical fault isolation and failure analysis. Once a chip has failed production test flow (or returned from a customer), the first step in this flow is to verify that the chip fails in debug lab. Once the chip is confirmed to fail in the debug lab environment, failure logs are then collected for further analysis. A scan-based logic fault diagnosis tool can process the failure data and provide a list of signals of interest. With the suspect structures identified by a scan-based diagnosis tool, debug engineer can then start physical fault isolation and failure analysis.

With the advances of CMOS technology, the defects that cause subtle timing failures have become a more important issue. Timing failures can be caused by circuit marginality, resistive interconnects, or process variations. Some conventional physical fault isolation techniques that capture static images or use static stimulation technologies can be used to identify static defects and leakage issues. These conventional techniques are discussed, for example, in D. Bockelman, et al., “Infrared Emission-Based Logic State Imaging on Advanced Silicon Technologies”, Proc. ISTFA, 2002, pp. 531-537, M. Bruce, V. Bruce, “ABCs of Emission Microscopy”, Electronic Device Failure Analysis, Vol. 5, Issue 3, 2003, pp. 13-20, K. Nikawa and S. Tozaki, “Novel OBIC Observation Method for Detecting Defects in Al Stripes Under Current Stressing”, Proc. ISTFA, 1993, pp. 303-310, and R. A. Falk, “Advanced LIVA/TIVA Techniques”, Proc. of ISTFA, 2001, pp. 59-65, each of which is incorporated entirely herein by reference. While these fault isolation techniques are still important, they may not be able to capture the critical timing information of a dynamic failure.

Recently, several fault isolation techniques that use laser stimulation and alternation have been developed. For example, with some techniques, a laser voltage probe (LVP)[06] acquires voltages of target signals through laser probing. (See, e.g., W. M. Yee, M. Paniccia, T. Eiles, V. Rao, “Laser Voltage Probe (LVP): A Novel Optical Probing Technology for Flip-Chip Packaged Microprocessors”, Proc. IPFA, 1999, pp. 15-20, which is incorporated entirely herein by reference.) Still other techniques use laser beam to alter the behavior of a defect such that the circuit can change from pass to fail or from fail to pass with the alteration. (See, e.g., T. Eiles, J. A. Roelette, “Critical timing analysis in microprocessors using near-IR laser assisted devices alteration (LADA)”, Proc. ITC, 2003, pp. 264-273, and B. Bruce, V. Bruce, D. Eppes, J. Wilcox, E. Cole Jr., P. Tang, F. F. Hawking, R. Ring, “Soft Defect Localization (SDL) in Integrated Circuits using Laser Scanning Microscopy”, Proc. ISTFA, 2002, pp. 21-27, each of which is incorporated entirely herein by reference.)

While the laser stimulation techniques are effective in isolating dynamic failures, they are invasive techniques and require proper control of a laser beam to avoid permanently damaging the circuit under debug. Instead of using a laser beam to stimulate the circuit under debug, other techniques, such as the picosecond imaging circuit analysis (PICA) technique and the time-resolved emission (TRE) technique have been developed. These techniques are described in more detail in, for example, J. C. Tsang, J. A. Kash, D. P. Vallett, “Picosecond imaging circuit analysis”, IBM Journal of Research and Development, 44(4), 2000, pp. 583-604, J. C. Tsang, J. A. Kash, and D. P. Vallett, “Time-resolved optical characterization of electrical activity in integrated circuits,”, Proc. of ITC, 2000, pp. 1440-1459, and D. R. Knebel et al., “Diagnosis and characterization of timing-related defects by time-dependent light emission”, Proc. ITC, 1998, pp. 733-73, each of which is incorporated entirely herein by reference. These techniques are non-destructive fault isolation techniques in that they are passive and do not modify the circuit under debug. Another advantage of the time-resolved emission technique is that the timing information can be accurately captured during the debug process, which provides important information for timing delay defects. The time-resolved emission technique in particular has become predominant in the advanced circuit debug activities.

A time-resolved emission system captures photon emissions from the backside of a circuit while a CMOS transistor is switching from the OFF state to the ON state, and provides a timestamp of each transistor switching activity. The analysis of the reconstructed time stamp and transistor switching activities provides valuable information to understand the operation of a specific transistor. The implementation and use of various time-resolved emission systems for timing failure debug and failure analysis for rapid product ramp up and fabrication yield analysis have been discussed in a variety of publications, including, for example,
D. Bodoh, E. Black, K. Dickson, et al., “Defect Localization using time-resolved photon emission on SOI devices that fail scan tests”, Proc. ISTFA, 2002;
E. Varner, C. Yong, H. Ng, T. Eiles, B. Lee, “Single Element Time Resolved Emission Probing for Practical Microprocessor Diagnostic Application”, Proc. Int'l Symp. Test & Failure Analysis, 2002, pp. 451-460;
R. Desplats, F. Beaudoin, P. Perdu, ‘Fault localization using time resolved photon emission and STIL waveforms’, Proc. Int'l Test Conf., 2003, pp. 254-263;
M. Remmach, A. Pigozzi, R. Desplats, P. Perdu, D. Lewis, J. Noel and S. Dudit, “Light emission to time resolved emission for IC debug and failure analysis”, Microelectronics and reliability, Vol. 45, No. 9-11, 2005, pp. 1476-1481;
H. W. Wong, P. F. Low and V. K. Wong, “Circuit Debug using Time Resolved Emission (TRE) Prober—A Case Study,” ICSE 2006, pp. 637-640;
C. Burmer, S. Gorlich, “Failure analyses for debug and ramp-up of modern IC's”, Microelectronics and Reliability Volume 46, Issues 9-11, 2006, Pages 1486-1497;
P. Egger, M. Grutzner, C. Burmer and F. Dudkiewicz, “Application of time resolved emission techniques within the failure analysis flow”, Microelectronics and Reliability, Vol. 47, Issues 9-11, 2007, pp. 1545-1549; and
J. Ferrigno, P. Perdu, K. Sanchez, D. Lewis, Identification of process/design issues during 0.18 um technology qualification for space application, in Proc. DATE, 2007, pp. 989-993
   each of which is incorporated entirely herein by reference.

With the continuous technology advancement and CMOS scaling, however, especially with the low-power designs and decreasing feature size of each technology node, there are several challenges to be met for the time-resolved emission technique to continue to be effective in silicon debug. For example, decreasing feature size and lower power design makes photon detection slower. Further, higher current density and associated noise around a target signal may create some noise emission that impacts the regular photon detection of the target signal. As a result, it is getting more time-consuming to accumulate enough photons to provide meaningful statistics for an analysis. Still further, in a circuit layout, it is quite common that transistors of a complex gate are placed close to each other. While only one transistor could be of interest, the emissions from other nearby transistors may also be captured by a time-resolved emission technique, which causes noise in the captured emission. This is especially significant for PMOS transistors, where the photon emission is about 10 times weaker than with an NMOS transistor. This kind of noise emission from neighboring transistors impacts the efficiency of a time-resolved emission system, and sometimes may even completely overshadow the switching activities of the target transistors.

Another challenge to the process of microcircuit debug comes from the recent innovation in scan design techniques. In the last five years, scan compression logic has been commonly adopted to reduce the cost of testing an integrated circuit. See, e.g., J. Rajski et al., “Embedded Deterministic Test for Low Cost Manufacturing Test,” Proc. ITC, 2002, pp. 301-310, and S. Mitra, K. S. Kim, “X-compact: an efficient response compaction technique”, IEEE Trans. On CAD, Vol. 23, No. 3, 2004, pp. 421-432, each of which is incorporated entirely herein by reference. Scan compression logic compresses multiple internal scan chain outputs to a single output channel, however, which makes the signal observation more difficult for a scan-based design. The reduced observability makes it harder to diagnose failures from a defective chip.

For example, when performing a guided probe on a design, debug engineers start tracing backward from a failing scan flip-flop for traditional scan designs. The tracing process continues until it reaches a signal where it shows no failure at its input (or driver) but shows failures at the output (or receiver). For a design with scan compression logic, however, given a failure at a tester channel and depending on the scan compression ratio, there may be tens or even hundreds of possible scan flops as probing candidates because multiple scan chains are feeding into the same tester channel. This makes the guided probing technique a very time consuming process. While using by-pass test patterns makes it easier to identify the failing flop, by-pass patterns usually have much longer scan chains and require much longer cycle times to loop a scan test pattern in order to activate a defect. Also, while repeating specific defect activation values during a single scan load operation can effectively reduce the debug time, this solution may not be applicable to designs with scan compression logic where the scan chains are much shorter than by-pass mode scan chains.

### BRIEF SUMMARY OF THE INVENTION

Aspects of the invention relate to the use of a scan-design structure and scan-based test generation techniques to improve debug efficiency using time-resolved emission techniques. Various implementations provide a debug flow that uses debug-friendly test patterns and logic fault diagnosis techniques to help physical fault isolation of timing failures. While specific examples of the invention are described in the context of use with time-resolved emission techniques, various implementations of the invention can be applied to other physical isolation techniques where signal transitions are measured, such as laser voltage probe (LVP) techniques and e-beam probing techniques.

### BRIEF DESCRIPTION OF THE DRAWINGS

FIG. 1 illustrates a microcircuit debug flow with debug-friendly test patterns.

FIG. 2 illustrates an example of a pseudo-robust transition propagation that may be provided according to various examples of the invention.

FIG. 3 illustrates an example of the management of neighborhood signals according to various examples of the invention.

FIG. 4 illustrates an example of a transition of a target net being propagated to the output of each fan-out branch gate according to various examples of the invention.

FIG. 5 illustrates an example of single chain observation for designs with scan compression logic according to various examples of the invention.

FIG. 6 illustrates a schematic of a circuit tested using an implementation of the invention.

FIG. 7 illustrates the waveforms for the circuit schematically shown in FIG. 6 collected from a time-resolved emission system.

FIG. 8 illustrates a highly resistive via causing a fault in the circuit schematically shown in FIG. 6.

### DETAILED DESCRIPTION OF THE INVENTION

### Illustrative Debug Flow

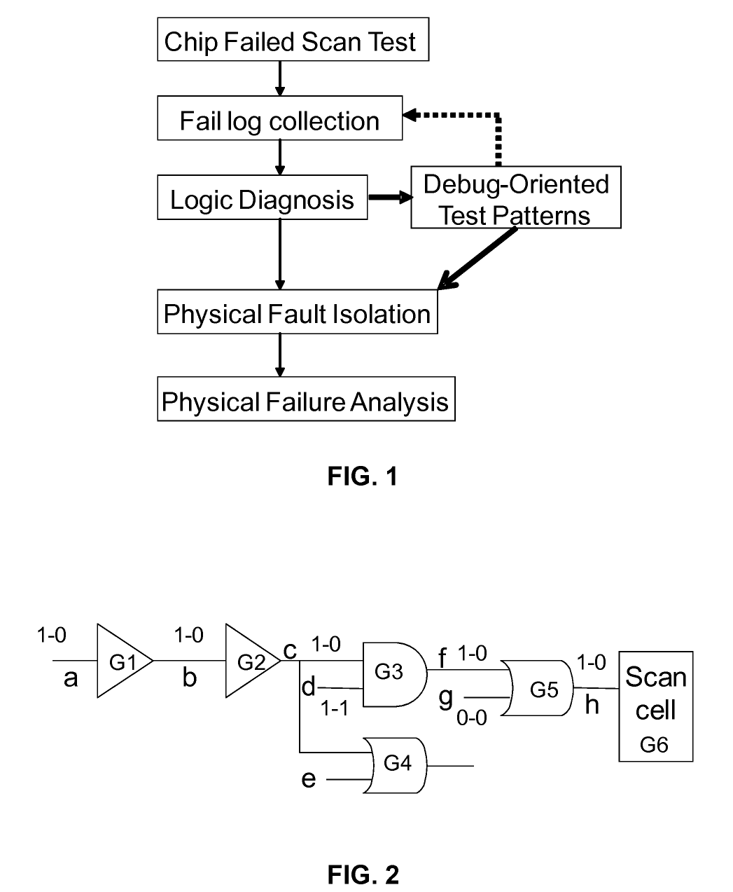

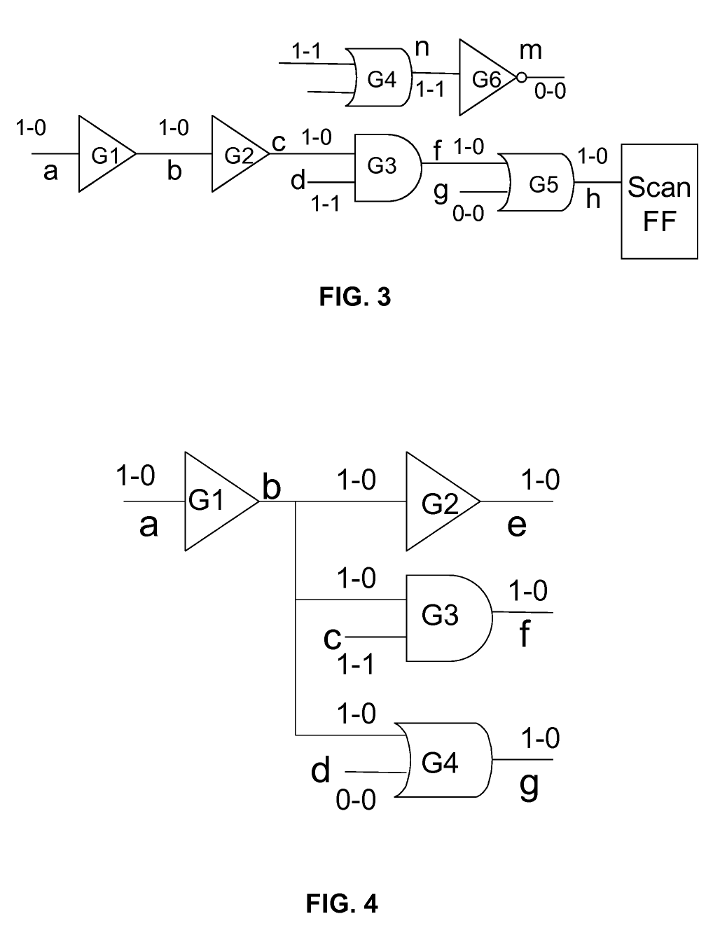

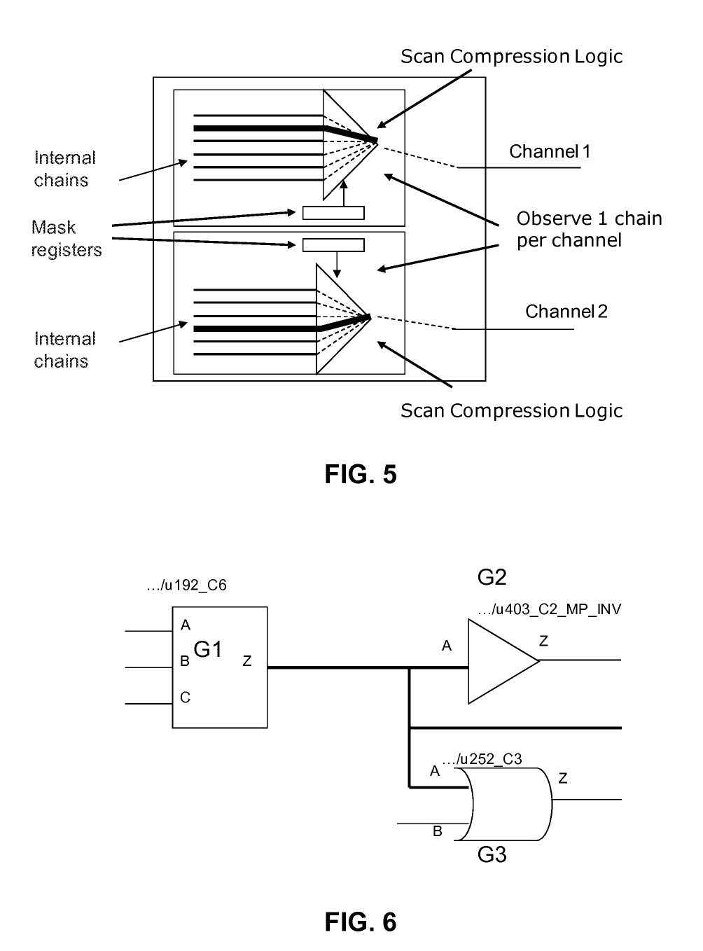

FIG. 1 shows the flow chart of an example of a debug flow that may be implemented according to various examples of the invention. As seen in this figure, a chip is first confirmed to fail production scan tests. Then, a failure log is collected for initial logic fault diagnosis. See, for example, R. Desineni et al., “A Logic Diagnosis Methodology for Improved Localization and Extraction of Accurate Defect Behavior”, in Proc. ITC, 2006, and M. Sharma et al., “Faster Defect Localization in Nanometer Technology based on Defective Cell Diagnosis”, Proc. ITC, 2007, Paper 15.3, each of which is incorporated entirely herein by reference. Since the production scan test patterns focus on fault detection instead of fault diagnosis and debug, the failing test patterns from the production test set may not be able to achieve a good diagnosis resolution or may not provide a good test pattern for further physical fault isolation.

At this point, a debug flow according to various examples of the invention takes the initial diagnosis report as input and generates additional scan test patterns to facilitate an effective debug process. As will be discussed in more detail below, these debug-friendly test patterns focus on the signals reported in the initial diagnosis report. For each signal in the diagnosis report, it generates 2-cycle transition delay test patterns and propagates the fault effects to primary outputs and scan cells for failure observation. As stated earlier, one purpose of the newly created transition test patterns is to improve the efficiency of silicon debug using, for example, a time-resolved emission system. Further, if the initial diagnostic resolution is not sufficient, the new patterns can also be applied to the circuit under debug on a tester to collect additional tester failures, and the newly collected failure logs can then be fed to a logic fault diagnosis tool to further improve diagnostic resolution. The diagnosis resolution improvement can be achieved by an iterative loop (shown as a dotted line in Error! Reference source not found.).

### Debug-Friendly Test Pattern Generation

As previously noted, the time-resolved emission technique captures photon emissions when a CMOS transistor switches from OFF state to ON state. Various implementations of the invention generates 2-cycle transition delay test patterns to make the test pattern debug-friendly for time-resolved emission systems.

### Pseudo-Robust Transition Propagation

In order to detect photon emissions, a time-resolved emission system usually loops a failing test pattern to continuously stimulate the circuit under debug. Using a failing pattern ensures that the defect has been activated and its impact is propagated for failure detection. By tracing back from the failing scan cell or primary output, a defect can be localized to a signal where its input values are as expected but the output values are defective. The propagation of a transition is important when the guided probe tracing is needed to identify a defect location. This could happen when there are multiple defects on a chip while the logic diagnosis cannot identify a high confidence suspect. In this case, failure analysis engineer will simply trace back from one of the failure observation points, until the defect is reached.

For each suspect signal in the initial diagnosis report, various examples of the invention will generate transition scan test patterns targeted to propagate transitions from a suspect signal to an observation point. In order to make sure that the transition propagated to an observation point is indeed coming from the target signal, during test generation, extra constraints are added to the logic gates along the propagation path such that there are no transitions on side inputs of the propagation path. This is a more stringent requirement than the test generation for robust test of a path delay fault or the test generation for propagation delay fault. To achieve this result, the test generation engine adds extra constraints on the side input signals so that they do not impact the transition on the target signal to be propagated along a path all of the way to a scan flop. It should be noted that, in order to have the “transition” along the path, the side inputs along the propagation path need to be constrained to non-critical values at both cycles.

An example of a pseudo-robust transition propagation that may be provided by a test generation engine according to various examples of the invention is shown in FIG. 2. In this example, a 1→0 transition at signal a is targeted, in order to propagate this transition to scan cell G6. Further, a test generation engine according to various examples of the invention adds constraints on the side inputs of gates G3 and G5 (i.e. signals d and g) to non-critical values. This guarantees the transition propagation from gate a to the scan cell G6 is not being impacted by the side inputs.

The benefit of using this pseudo-robust transition test pattern with a time-resolved emission debug system can be viewed in two aspects. First, during a guided probe debug, the debug engineer can trace the failure from a failing scan flop all the way back to the defective area by tracing a single thread of transition along the path, so there is no need to probe multiple inputs at each logic level. Second, noise emission from the complex gate can be reduced because there is no transition on any side inputs along the transition propagation path.

### Neighborhood Transition Reduction

The impact of neighborhood signals on a defect excitation has been studied in the past, and the extracted neighborhood information can be used to further improve logic diagnosis resolution. With various examples of the invention, neighborhood signals can be selectively generated for better physical fault isolation during timing failure debug. To capture the waveforms of a signal in the circuit, a transition on that signal should be created so that there will be photon emission coming out of a relevant transistor during its state transition. For a complex gate, the layout design may place transistors of several logic gates in one close area. Noise photon emissions from neighboring signals may cause some fake pulses during the waveform capturing process. To improve the effectiveness of waveform capturing, during the test generation process, the test generation procedure according to various examples of the invention may be optimized to reduce the transitions of neighboring signals. The neighboring signals may include, for example, the signals in a logic and physical neighborhood defined by a user. With some implementations of the invention, a user may provide a list of neighboring signals for a target net. With still other implementations of the invention, however, an automated flow to extract neighboring signals from a layout database may be alternately or additionally employed. The reduced transitions on neighboring signals reduces the noise during photon emission capturing process, thereby helping a time-resolved emission system to clearly capture the emissions of the target signals

One example of the management of neighborhood signals according to various examples of the invention is shown in Error! Reference source not found. This example assumes there is a transition 1→0 on net f. In order to reduce the noise on the neighboring nets n and m, the test generation procedure according to various examples of the invention constrains no transition on nets n and m during test generation such that there is no emission from gates G4 and G6 during debug. The reduced neighboring signal transition enables more accurate photon emission detection of the target signal.

### One Level Transition Propagation to all Branches

In order to localize a defect on a large net, a test generation algorithm according to various examples of the invention may employ extra constraints to sensitize all of the branches of each net to its next logic gate level. With these implementations, the side-inputs of all of the fan-out branches will be constrained to non-critical values so that the transition of the target net can be propagated to the output of each fan-out branch gate. During physical failure isolation, the switching activities of all of the branch signals can be detected by the time-resolved emission system. Based on whether a switching activity is observed on a branch or not, it can quickly be concluded which branch is impacted by the defect. This is very effective in isolating a defect to a segment of the target net when there are a large number of fan-outs on the net when the defect only impacts a small number of fan-out branches.

An example of the transition of the target net being propagated to the output of each fan-out branch gate according to various examples of the invention is shown in Error! Reference source not found. In this example, in order to know whether net b has a defect, a debug pattern is created with a transition on net b. Further, extra automatic test pattern generation (ATPG) constraints are added during test generation process such that the transition on net b can be propagated to all the fan-out branches. With the debug friendly test pattern according to various examples of the invention, the transition activities on all of the fan-out branches can be detected by using a time-resolved emission system. If all of the three branches are failing, then it is most likely the stem of this net that is failing. Otherwise, if only some of the branches are failing while the other branches are passing, then it can be concluded that the defect is on the net segment that is exclusively feeding the failing branches.

Support Designs with Scan Compression Logic

For designs that employ scan compression logic, multiple scan chains are compressed into a single output channel. Scan chain output values are not observed directly on a tester, however. When debugging a failing chip with scan compression logic, the first step to isolate a defect is to identify the failing scan chain and the failing scan cell.

With a debug-friendly test generation engine according to various examples of the invention, the masking registers are controlled in the scan compression logic and forced to observe a single internal scan chain at each output channel, as shown in Error! Reference source not found. By observing a single internal scan chain at each output channel, any failure observed on a tester can be mapped uniquely to a single internal scan chain. The corresponding scan cell can be identified from the failing shift cycle. With the debug-oriented test pattern, debug engineer can easily identify the unique failing scan flop of each failing output channel for any failing scan test pattern.

### Constraints

Compared to regular scan test pattern generation flows, some test pattern generation techniques according to various examples of the invention may require more ATPG constraints to generate debug-friendly test patterns. During debug pattern generation, for example, the ATPG limit (e.g. CPU time limit) may be increased while targeting a fault. In practice, this increase in the ATPG constraints will not have significant impact on the success rate in creating debug-friendly test patterns. Even though, for each target fault, the test generation time might be longer than a conventional ATPG process, in general the overall test generation time is not a concern due to the small number of faults to be targeted by the debug pattern generation flow.

### Implementation Example

One implementation of a debug test pattern generation technique according to various examples of the invention was applied to an industry design during product debug. The design was manufactured at 90 nm technology. The production scan test patterns for stuck-at faults show that a chip failed stuck-at test patterns. Failure logs were collected, and logic fault diagnosis showed that the diagnosis suspect with the highest score was an “Open/Dom” fault, as shown in report excerpt below:

symptom = 1 #suspects = 1 #explained_patterns = 94

| ID | score | type | value | pin_name | cell_name | net_name |
|---|---|---|---|---|---|---|
| 1 | 98 | OPEN/DOM | both | ..u_r99_pp/u_r99_pp_afc/u192_C6/Z | R_SOND1YX040 | ../u_r99_pp/u_r99_pp_afc/t5_afc_en |

symptom = 2 #suspects = 9 #explained_patterns = 11

| | | | mis- | | | | | |
|---|---|---|---|---|---|---|---|---|
| ID | score | fail_match | match | type | value | pin_name | cell_name | net_name |
| 1 | 91 | 11 | 0 | OPEN/ | both | /BW2_INV60931/Z | LL_SIVYX160 | /bd_scan_inst/core_i/core_inst/dfe_i_o_4_7 |
| | | | | DOM | | | | |
| 2 | 69 | 11 | 5 | OPEN/ | both | /BW2_INV60931/A | LL_SIVYX160 | /bd_scan_inst/core_i/core_inst/dfe_i_o_4_5 |
| | | | | DOM | | | | |

The “Open/dom” fault reported by the diagnosis tool models the defect behavior of a floating net, or a net dominated by another signal due to a bridging defect. The schematic of the suspect signal is shown in FIG. 6. From this schematic, it can be seen that the suspect is a net with several fan-out branches.

Since the diagnosis suspect had a score of 98 (where the maximum score is 100) with a single net, there was no need to further improve the diagnostic resolution for this test case. Physical fault isolation focused on this net. However, inspection by using static emission detections TIVA did not show any sign of abnormality in the suspect area, leading to the hypothesis that the fault could be a timing failure caused by a high resistive via or interconnect.

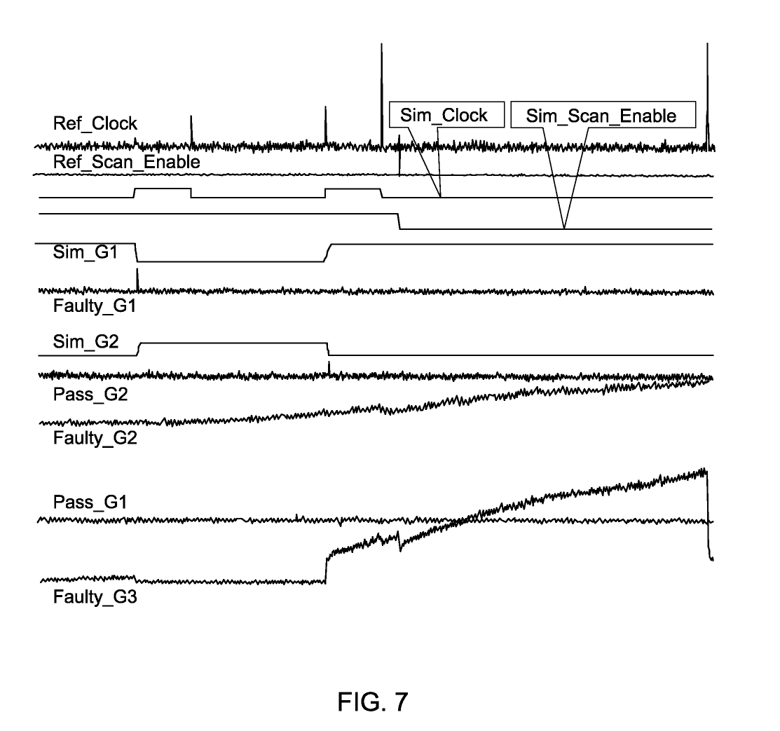

In order to perform physical fault isolation, additional debug-friendly transition test patterns were created that focused on the failing signals. The new test patterns were transition test patterns that were optimized to provide better transitions for the time-resolved emission system to capture photon emissions in the area of interest. FIG. 6 shows the values of the suspect net from the simulator. The waveforms for the test circuit collected from the time-resolved emission system are shown in FIG. 7. To show the abnormal behavior of the defective chip, the defective chip was compared with a known good chip. The waveforms labeled with “pass_ . . . ” are those for the good chip, while the waveforms labeled with “Faulty_ . . . ” are for the defective chip. The waveforms starting with “Logic_” are the logic values derived from the corresponding emission histograms. As a reference, the time-resolved emission system waveforms of the clock and the scan enable signals are also included in this figure as “ref_clock”, “ref_scan_enable”, “Logic_clock”, “Logic_scan_enable”. It should be noted that the waveforms from the time-resolved emission system shows the photon emissions while the logic waveforms show the binary values 0 or 1.

From the waveforms, it can be seen that the inverter (G2) shows the light emission increases slowly while its output should have a 1→1 transition. The other branch, with an OR gate (G3), shows no sign of transition during the launch cycle (the first clock cycle). This is due to the side input (input B) of gate G3 having a constant value of 1 during this cycle and blocks the signal propagation from the other input A. However, in the capture cycle (the second clock cycle), the side input B of gate G3 changed from 1 to 0, and starting from that point, it can be seen that the output of the gate G3 starts showing increasing photon emissions.

For gates G2 and G3, when compared to the reference “good” circuit waveforms, it can be seen that the excessive long photon emission period in the defective chip indicates a long switching time and slow transistor transition from the OFF state to the ON state. However, at the input of the suspect net, the waveforms of gate G1 match between the defective chip and the good reference chip. This indicates that the defect is on this net, and most likely it is a resistive via on this net. Further, since both branches are impacted by this defect, the location of the defect must be on the stem of these two branches. For this debug case, focusing on the stem of this net eliminates 40% of vias on the net from needing to be further inspected. Physical failure analysis later confirmed that the defect was a highly resistive via that impacted the timing of this net, as illustrated in FIG. 8.

From the waveforms of gates G2 and G3 obtained from the time-resolved emission system, the size of the delay caused by this defect is large enough such that its impact can be captured by some stuck-at test patterns when the last shift in values activate the defect. This explains why the chip failed production stuck-at test patterns. However, with the well defined transition timing in debug-friendly transition test patterns, it is much easier to capture the defect behavior using debug patterns than using stuck-at test patterns.

### CONCLUSION

While the invention has been described with respect to specific examples including presently preferred modes of carrying out the invention, those skilled in the art will appreciate that there are numerous variations and permutations of the above described systems and techniques that fall within the spirit and scope of the invention as set forth in the appended claims. For example, while specific terminology has been employed above to refer to electronic design automation processes, it should be appreciated that various examples of the invention may be implemented using any desired combination of electronic design automation processes.

1. (canceled)

2. (canceled)

3. A method of debugging a circuit, comprising.
identifying a target signal in a circuit that may propagate a fault;
generating transition delay test patterns to propagate the fault along the target signal;
applying the transition delay test patterns to the target signal;
monitoring devices along a path of the target signal to identify a physical location of the fault;
identifying side signals for devices in fan-out branches of a net along the path of the target signal; and
applying constraint values to the side signals so that the side signal so that a transition on the test signal created by a transition delay test pattern is propagated to outputs of the devices in the fan-out branches.

4. A method of timing failure debug, comprising:
selecting a target signal region in a circuit where a timing-related defect may exist and a propagation path that passes through the target signal region to an observation point where a timing failure caused by the timing-related defect can be observed;
generating, under one or more constraints, a test pattern that can activate the timing-related defect and propagate the timing failure along the propagation path, the one or more constraints including a first constraint that some or all side inputs along the propagation path are set to non-controlling values;
applying the test pattern to the circuit; and
monitoring the circuit along the propagation path using a transition signal measurement technique.

5. The method recited in claim 4, wherein the one or more constraints further include a second constraint to reduce noise coming from one or more neighboring signal regions.

6. The method recited in claim 5, wherein the second constraint is a constraint that attempt to reduce or eliminate transitions in the one or more neighboring signal regions.

7. The method recited in claim 5, wherein the one or more neighboring signal regions is provided by a user or is extracted from layout data of the circuit.

8. The method recited in claim 4, wherein the one or more constraints further include a third constraint that one or more side inputs on fan-out branches of the target signal region are set to non-controlling values.

9. The method recited in claim 4, wherein the one or more constraints further include a fourth constraint to allow a single internal scan chain where the observation point is located to be observed at an output channel of a scan compression logic.

10. The method recited in claim 9, wherein the fourth constraint involves controlling masking registers in the scan compression logic.

11. The method recited in claim 4, wherein the transition signal measurement technique is a time-resolved emission (TRE) technique.

12. The method recited in claim 4, wherein the test pattern is a 2-cycle transition delay test pattern.

13. The method recited in claim 4, wherein the one or more constraints are ATPG constraints and the generating uses an ATPG process.
